(19) United States
(12) Patent Application Publication
(10) Pub. No.: US 2026/0259782 A1
(43) Pub. Date: Sep. 3, 2026

(54) LOAD BALANCING FOR A LARGE MODULAR SYSTEM

(71) Applicant: Arista Networks, Inc., Santa Clara, CA (US)

(72) Inventors: Man Him Andrew HO, Santa Clara, CA (US); Jason Edward CHAN, San Jose, CA (US); Daehwan Daniel KIM, Sunnyvale, CA (US); Youngbae PARK, Milpitas, CA (US); Paulmer SODERBERG, Palo Alto, CA (US); James Alden WEAVER, Palo Alto, CA (US)

(21) Appl. No.: 19/067,278

(22) Filed: Feb. 28, 2025

(51) Int. Cl. G06F 9/50; H01R 12/75

(52) U.S. Cl. CPC G06F 9/505; H01R 12/75

(57) ABSTRACT

An apparatus comprising first plurality of components mounted to a first printed circuit board (PCB), a hybrid connector mounted to the PCB and connected to the first plurality of components, a second plurality of components and a plurality of signal paths through the hybrid connector, the plurality of signal paths connecting each of the first plurality of components to each of the second plurality of components. The signal paths may be load balanced such that, for example, the plurality of signal paths forms an equal number of data lanes between each of the first plurality of components and each of the second plurality of components.

### TECHNICAL FIELD

This disclosure relates generally to computer system architecture. More particularly, embodiments relate to modular computer systems. Even more particularly, embodiments relate to load balancing for modular systems.

### BACKGROUND

Network devices, such as switches, routers, gateways, and other types of network devices, may include network processors to handle forwarding decisions for forwarding traffic (e.g., to handle Layer 2 switching or Layer 3 switching/routing). In high-capacity network devices, the network processors may be implemented as application specific integrated circuits (ASICs). An ASIC can be orders of magnitude faster than a programmed central processing unit (CPU) for forwarding packets.

A large network device may, for example, include a line card with a switching network processor (e.g., a switching ASIC or other switching network processor) and the backplane may include a fabric network processor (e.g., fabric ASIC or other fabric network processor). A switching network processor, such as a switching ASIC, provides packet forwarding and may perform, for example, Layer 2 switching or Layer 3 routing. A switching network processor may also provide functionality such as quality of service, traffic shaping and policing, protocol handling and other network traffic processing functionality. A fabric network processor, such as a fabric ASIC, provides a fabric for transferring traffic between components of a modular network device. A fabric network processor may, for example, implement internal forwarding of traffic between ingress and egress ports connected to different switching network processors (e.g., switching ASICs) or on different line cards.

As the bandwidth of network processors increases, there is an increasing demand for network devices that can connect more computing devices together. While multiple network processors can be used to increase bandwidth, increasing the number of network processors presents a number of challenges. First, adding more network processors requires more board space on the printed circuit board (PCB) to accommodate the additional processors, potentially requiring a PCB that is too large to be practical or manufacturable. Second, even if the PCB could be manufactured, the long traces from network processors—for example, long traces from network ASICs to backplane connectors—can lead to unacceptable insertion losses, particularly at high data rates. Although repeater devices, such as retimers or redrivers, may be used to decrease insertion loss over long traces, repeater devices have several drawbacks including increased power consumption, increased heat generation, increased board complexity, increased cost, and additional latency.

### BRIEF DESCRIPTION OF DRAWINGS

The drawings accompanying and forming part of this specification are included to depict certain aspects of the disclosure. It should be noted that the features illustrated in the drawings are not necessarily drawn to scale. A more complete understanding of the disclosure and the advantages thereof may be acquired by referring to the following description, taken in conjunction with the accompanying drawings in which like reference numbers indicate like features.

FIG. 1 is a diagrammatic representation of one embodiment of a modular network device.

FIG. 2A is a diagrammatic representation of one embodiment of a line card.

FIG. 2B is a diagrammatic representation of one embodiment of a fabric card.

FIG. 3A is a diagrammatic representation of a front oblique view of one embodiment of a hybrid connector.

FIG. 3B is a diagrammatic representation of a rear oblique view of one embodiment of a hybrid connector.

FIG. 3C is a diagrammatic representation of a partially exploded view of one embodiment of a hybrid connector.

FIG. 4A and FIG. 4B are diagrammatic representations of one embodiment of the allocation of signal paths for load balancing.

FIG. 5 is a diagrammatic representation of one embodiment of a cable harness.

FIG. 6 is a diagrammatic representation of a side-by-side arrangement of one embodiment of a hybrid connector.

FIG. 7 is a diagrammatic representation of one embodiment of a hybrid connector having a stacked arrangement.

FIG. 8 is a diagrammatic representation of one embodiment of a hybrid connector having a side-by-side arrangement.

FIG. 9A is a diagrammatic representation depicting a first view of one embodiment of a back-to-back arrangement of printed circuit boards (PCBs).

FIG. 9B is a diagrammatic representation depicting a second view of one embodiment of a back-to-back arrangement of printed circuit boards (PCBs).

FIG. 10 is a diagrammatic representation of one embodiment of a modular network device.

FIG. 11 is a diagrammatic representation depicting a first view of one embodiment of a fabric card.

FIG. 12 is a diagrammatic representation depicting a second view of one embodiment of a fabric card.

FIG. 13 is a diagrammatic representation of one embodiment of a line card.

FIG. 14 is a diagrammatic representation of one embodiment of a line card connected to one embodiment of a fabric card.

### WRITTEN DESCRIPTION

Embodiments and the various features and advantageous details thereof are explained more fully with reference to the non-limiting embodiments that are illustrated in the accompanying drawings and detailed in the following description. Descriptions of well-known starting materials, processing techniques, components and equipment are omitted so as not to unnecessarily obscure the embodiments in detail. It should be understood, however, that the detailed description and the specific examples are given by way of illustration only and not by way of limitation. Various substitutions, modifications, additions and/or rearrangements within the spirit and/or scope of the underlying inventive concept will become apparent to those skilled in the art from this disclosure.

The present disclosure provides systems and methods for connecting and routing signal paths between processors or other components of a computer system using, in some embodiments, one or more of hybrid connectors, optimized cable harnesses, and back-to-back processor arrangements to achieve a desired load balancing scheme.

According to some embodiments, a hybrid connector comprises a stacked board mount connector and cable connector in an assembly. The board mount connector comprises a board mount side that is mountable to a PCB. The board mount connector has a mating interface for mating with a non-board mount connector, such as a mating cable connector. The mating interface includes contacts that are connected to the board mount contacts of the board mount connector. The cable connector is mounted to the board mount connector away from the board mount side (and away from the PCB when assembled on a PCB). The cable connector terminates in a plurality of cables and has a mating interface comprising contacts connected to the cables.

In some embodiments, the signal trace from the board mount connector portion of the hybrid connector travels a relatively short distance to connect to a processor or other component which is near to the connector such that no repeater device (e.g., retimer or redriver) is required. Further, the cable connector portion of the hybrid connector may be connected by low insertion loss cables to a processor or other component that is farther away such that, again, no repeater is needed. A hybrid connector can thus reduce or eliminate the need for repeaters between the processors and connector while requiring fewer cables compared to implementing the same number of data lanes using an all-cabled connector. As such, a hybrid connector-based approach can support high data rates without the use of repeater devices in the signal paths while also avoiding bulky cabling harnesses that require excessive volume and severely impact air flow and cooling.

Further, some embodiments described herein provide another advantage by reducing board space compared to a side-by-side arrangement of connectors. A larger board results in longer trace lengths and increased insertion loss. The stacked arrangement of some embodiments of hybrid connectors helps maintain a smaller board size and hence lower insertion losses in traces.

According to one aspect of the present disclosure, an apparatus (e.g., a network device or other computer apparatus) comprises a first plurality of components, a second plurality of components a hybrid connector mounted to a PCB and connected to the first plurality of components and the second plurality of components, and a plurality of signal paths through the hybrid connector, the plurality of signal paths connecting the first plurality of components to the second plurality of components. In one embodiment, the plurality of signal paths connects each of the first plurality components to each of the second plurality of components such that, for example, there is at least one data lane between each component in the first plurality of components and each component in the second plurality of components. Preferably, the plurality of signal paths between the first plurality of components and the second plurality of components do not include repeater devices (e.g., retimers or redrivers)—that is, the signal paths are repeaterless signal paths, such as pass-through paths that do not require signal conditioning between the first plurality of components and the second plurality of components.

According to one embodiment, one or more of the components from the first plurality of components are mounted to the same PCB as the hybrid connector. In addition, or in the alternative, two or more components from the second plurality of components may be mounted to PCBs arranged in a back-to-back arrangement. According to one embodiment, the signal path lengths from the components mounted in the back-to-back arrangement to the hybrid connector are the same.

In one embodiment, at least one of the components in the first plurality of components comprises a processor. In addition, or in the alternative, one or more components in the second plurality of components comprises a processor. One or more processors in the first plurality of components may be a network processor. In addition, or in the alternative, one or more processors in the second plurality of components may be a network processor. In one embodiment, the first plurality of components comprises a first plurality of network processors and the second plurality of components comprises a plurality of network processors. The first plurality of network processors, according to one embodiment, comprises switching processors and the second plurality of network processors comprises fabric processors.

Thus, for example, in a modular device, a first plurality of components of a first module may connect to the hybrid connector and a second plurality of components in a second module may connect to the hybrid connector (e.g., via a mating connector) such that when the first module is connected to the second module the plurality of signal paths between the first plurality of processors and the second plurality of processors are formed. In one embodiment, the first module may be a line card and the second module a backbone module to which multiple line cards can connect. In an even more particular embodiment, the line card includes a plurality of switching processors and the second module is a fabric card that comprises a plurality of fabric processors, where the plurality of signal paths connects the plurality of switching processors to the plurality of fabric processors.

According to one embodiment, a mating connector can be mated to the mating interface of a hybrid connector. The mating connector may be connected by signal paths to the components in the second plurality of components. The connections from the mating connector may fan out to multiple components to distribute signal paths according to desired load balancing scheme. In some embodiments, the mating connector is a cable connector that terminates a cable harness where the cable harness connects signal paths from the hybrid connector to the second plurality of components. The cables of the cable harness can be segregated between the components to achieve the desired load balancing.

Embodiments of the present disclosure can provide for load balancing between network processors of line cards and the network processors of a backplane (e.g., switching fabric). According to one embodiment, a line card includes a hybrid backplane connector connected to switching network processors of the line card by traces and cable connections and the backplane includes a mating connector connected to fabric network processors of the backplane such that when the line card is connected to the backplane, there are signal paths between the switching network processors and the fabric processors with the signal paths allocated to achieve a desired load balancing. In an alternative embodiment, the backplane includes a hybrid connector connected to the fabric network processors and the line card includes a mating connector connected to the switching network processors. In some embodiments, both the backplane connector of the line card and the mating connector of the backplane are hybrid connectors.

In some embodiments, the signal paths between processors are configured such that no repeater devices are needed to compensate for insertion losses between the processors. As discussed above, the use of hybrid connectors can help mitigate the need for repeater devices, such as retimers. Further, some embodiments use a “back-to-back” processor arrangement. A back-to-back arrangement can use PCBs that are smaller than would be required to support the same number and type(s) of processors on a single PCB and facilitates the use of signal channels that meet the insertion loss requirements of components while reducing or eliminating the need for repeater devices. A “back-to-back” processor arrangement can also facilitate cooling. Thus, for example, one or more of a fabric card or a line card of a modular network device may use a back-to-back arrangement.

In some embodiments, the PCBs in a back-to-back arrangement in a network device each include a single network processor. However, to the extent multiple network processors can be included on a single PCB while meeting manufacturability and loss constraints, embodiments may include multiple network processors on one or more of the back-to-back PCBs.

According to one embodiment, the network processors of the back-to-back arrangement are connected to a plurality of nodes by respective signal channels. Examples of nodes include, but are not limited to network interfaces, network ports, and line cards. The signal channels between the network processors and the nodes comprise traces, signal channel cables, connectors or other components or combinations thereof to form electrical paths from the network processors to the nodes. In one embodiment, the signal channels between the network processors on the back-to-back PCBs and the nodes comprise signal channel cables, such as twinax signal channel cables, which run from board-to-cable connectors (e.g., terminal blocks) on the PCBs to node connectors (the connection to the nodes). The node connectors, according to one embodiment, are near package connectors (NPCs).

In one embodiment, the nodes are arranged in a row, spaced from the edges of the PCBs so that, for example, each node is, from a signal path perspective, approximately equidistant from the first network processor and the second network processor. As such, the lengths of the signal channel between the first network processor and a particular node and the second network processor and the same node are approximately the same. In one embodiment, the physical connections to the nodes (e.g., NPCs for connecting to the line cards, connectors to ports) are intersected by a plane (e.g., center plane) that passes between the pair of PCBs.

The network device is configured so that the signal channels satisfy the insertion loss requirements of each of the plurality of nodes. The insertion loss requirement for a signal channel between a network processor and a node will depend on the insertion losses and insertion loss specifications associated with the network processor and the node. For example, i) the network processor may have an associated insertion loss and insertion loss specification; and ii) the node may have an associated insertion loss and insertion loss specification. With respect to the node, for example, the node may include a node processor (e.g., a node ASIC) that has an associated insertion loss and insertion loss specification. Further the node may have an insertion loss for the portion of the signal channel between the node connection and the node processor.

Given the network processor insertion loss and the node insertion loss, an insertion loss requirement (allowable insertion loss) for the signal channel from the network processor to the node can be determined so that the total insertion loss of the complete channel between the network processor to the node processor satisfies the insertion loss specifications of the network processor and node processor. The components and arrangement of a signal channel can thus be selected so that the signal channel satisfies the insertion loss requirements of the network processor and the node. For example, signal channel cables, connectors, and traces can be selected so that the signal channel meets the insertion loss requirement.

In some embodiments, the PCBs in a back-to-back arrangement are identical to each other and assembled on a common frame structure. The common frame structure may provide attachment holes for various components, such as NPCs, network processor attachment or other components.

Embodiments of a network device may include various heat management features, such as fans, heat transfer devices, etc. that are adapted to transfer heat away from the network processors. According to one embodiment, a heat exchanger, heat chimney or other heat transfer device may be disposed to transfer heat away from the PCBs. Further, signal channel cables may be routed to minimize impact on air flow while still satisfying the insertion loss requirements.

In some embodiments, a back-to-back configuration may be used in one or more communications modules of a network device, such as in one or more fabric cards or line cards of the network device. Using the example of a fabric card, the fabric card may include back-to-back PCBs with fabric ASICs disposed on the front sides of the back-to-back PCBs. Each of the fabric ASICs can be connected to each of a plurality of NPCs by a respective signal channel that is configured to meet a signal channel budget selected so that the overall channel between the fabric ASIC and a switching ASIC on a line card satisfies the insertion loss specification of the fabric ASIC and the switching ASIC.

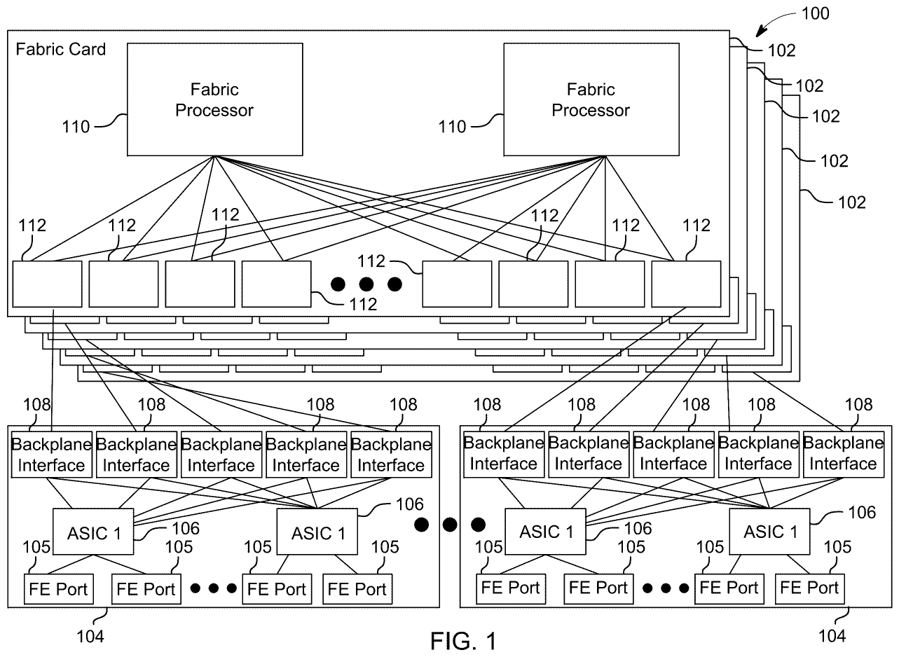

FIG. 1 is a diagrammatic representation of a data plane of a large modular network device 100 that comprises a plurality of fabric cards 102 and a plurality of line cards 104. In this example, network device 100 includes five fabric cards 102 and eighteen line cards 104 (two of which are illustrated). In some embodiments, one or more cards (fabric or switching) include hybrid connectors. Further in some embodiments, one or more cards uses a back-to-back arrangement. In any case, network device 100 is merely illustrated and embodiments of modular network devices are scalable and can include more or fewer fabric cards, line cards, network processors, etc.

Each line card (LC) 104 provides front-end ports 105 (e.g., ethernet ports or other network ports) for network connections. Each LC 104 also includes backplane connectors 108 for connecting to the signal paths of fabric cards 102 (as used herein “backplane connector” includes backplane connectors). In the illustrated embodiment, each LC 104 includes five backplane connectors 108 and can thus connect to each of the five fabric cards 102. According to one embodiment, one or more backplane connectors 108 of each LC 104 is a hybrid connector that includes a combination of a board mount connector and a cable connector. Each LC 104 also includes a pair of switching ASICs 106 (or other switching network processors), each of which is connected to respective subset of the front-end ports 105 and to each of the backplane connectors 108. The switching ASICs 106 provides packet forwarding and may perform, for example, Layer 2 switching or Layer 3 routing. The switching ASICs 106, for example, forward traffic between ports 105 of the respective LC 104 and traffic to/from the fabric cards 102. The switching ASICs 106 also provide functionality such as quality of service, traffic shaping and policing, protocol handling and other network traffic processing functionality.

Each fabric card (FC) 102 includes a pair of fabric ASICs 110 connected to a mating connector compatible 112 compatible with a respective backplane connector 108. Fabric ASICs 110 provide a fabric for transferring traffic between components of modular network device 100. Fabric ASICs implement internal forwarding of traffic between ingress and egress ports connected to different switching ASICs 106 on the same or on different LCs.

According to one embodiment, network device 100 is a high bandwidth system (e.g., 224 Gbps). Focusing on the LCs, the bandwidth between ASIC 1 and ASIC 2 of an LC 104 is preferably balanced across the fabric card connectors. As the data rates supported by network devices increase, insertion loss in board traces becomes very high. Possible options for addressing this problem include repeater devices to condition signals to compensate for loss, low insertion loss cables to minimize loss, or a combination thereof. Repeater devices, however, consume additional power and take up valuable space. Bulky cable harnesses also take up valuable space and can block air flow. Embodiments of the present disclosure can address these problems using a hybrid connector that provides an interface to both board traces and cables (e.g., low insertion loss cables). The hybrid connector allows for a reduced harness size compared to using low insertion loss cables for the same number of diff pairs as supported by the hybrid connector. The hybrid connector also reduces or eliminates the need for repeater devices for longer signal paths.

Network device 100 is one illustrative embodiment of a network device that incorporates one or more hybrid connectors. Hybrid connectors, however, may be used in a variety of network devices including, but not limited to, modular network devices that include a different number of fabric cards 102, fabric ASICs 110 per fabric card 102, connectors 112 per fabric card, line cards 104, front end ports 105, backplane connectors 108, or switching processors (e.g., switching ASICs 106) than illustrated in FIG. 1.

According to one embodiment, network device 100 comprises a plurality of signal paths through connectors 112 and backplane connectors 108. For example, the signal paths through a backplane connector 108 may include signal paths between each fabric ASIC 110 of a respective fabric card 102 and each switching ASIC 106 of the line card 104.

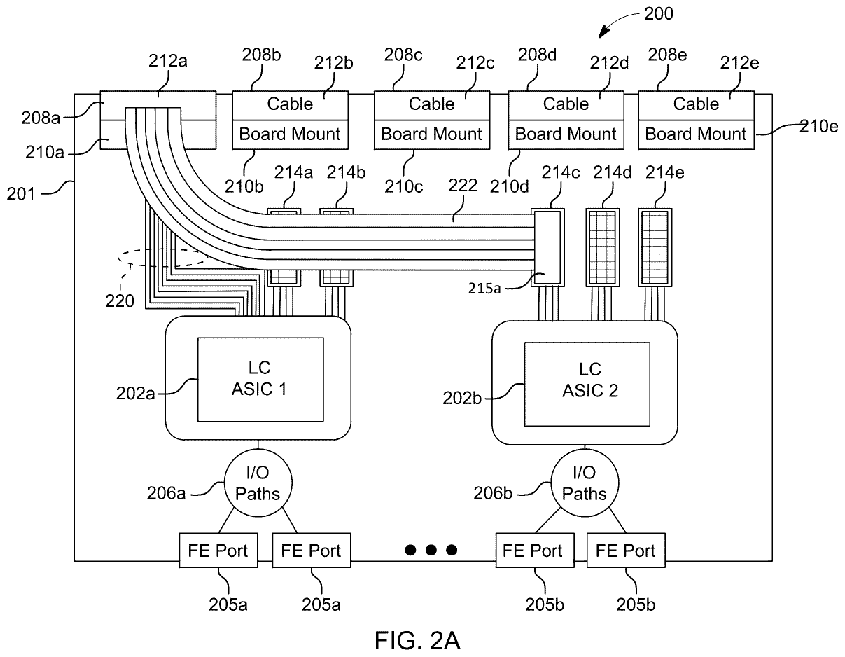

FIG. 2A is a diagrammatic representation of embodiment of a line card 200, which may be used, for example as an LC 104, in one embodiment. LC 200 includes switching ASIC 202a and switching ASIC 202b. LC 200 provides front-end ports (e.g., ethernet ports or other network ports) for network connections. Front end ports 205a connect to switching ASIC 202a via I/O paths 206a and front-end ports 205b connect to switching ASIC 202b by I/O paths 206b.

Each LC 200 also includes backplane connectors for connecting to the signal paths of fabric cards. In the illustrated embodiment, LC 200 includes five backplane connectors (backplane connector 208a, backplane connector 208b, backplane connector 208c, backplane connector 208d and backplane connector 208e) mounted to PCB 201. Each backplane connector of LC 200 is a hybrid backplane connector and includes a board mount connector and a cable connector. Thus, backplane connector 208a includes board mount connector 210a and cable connector 212a, backplane connector 208b includes board mount connector 210b and cable connector 212b, backplane connector 208c includes board mount connector 210c and cable connector 212c, backplane connector 208d includes board mount connector 210d and cable connector 212d, and backplane connector 208e includes board mount connector 210e and cable connector 212e. The hybrid connectors connect to a fabric card and, in even more particular embodiments, cable connectors of the fabric cards. In one embodiment, LC 200 can connect to multiple fabric cards with, for example, each backplane connector connecting to a different fabric card. LC 200 further includes cable-to-board connector 214a and cable-to-board connector 214b connected to ASIC 202a (e.g., by board traces), and cable-to-board connector 214c, cable-to-board connector 214d, and cable-to-board connector 214d connected to switching ASIC 202b (e.g., by board traces). According to one embodiment, cable-to-board connector 214a, cable-to-board connector 214b, cable-to-board connector 214c, cable-to-board connector 214d, cable-to-board connector 214e are terminal blocks.

According to one embodiment, for each backplane connector, half of the signal paths go to the ASIC which is nearer to the connector and the remaining half of the signal paths go to the ASIC which is far from the connector. Thus, according to one embodiment, the board mount connector of a hybrid connector connects to the nearest ASIC via board traces and the cable connector portion of the hybrid connector connects to the ASIC that is farther away via a cabled connection, though other schemes for connecting signal paths may be used.

In the embodiment of FIG. 2A, switching ASIC 202a has a short enough route to backplane connector 208a to be done by board trace. Thus, ASIC 202a is connected to board mount connector 210a via traces 220 and can thus forward and receive traffic through board mount connector 210a via traces. ASIC 202b, on the other hand, has a relatively long route to backplane connector 208a and is thus connected to cable connector 212a portion of backplane connector 208a via low insertion loss cables 222 that run from cable connector 212a to cable-to-board connector 215a, which mates with cable-to-board connector 214c.

The other connections between the ASICs and hybrid connectors are not illustrated in FIG. 2A to avoid obscuring other details. According to one embodiment, ASIC 202a connects via board traces to board mount connector 210b portion of backplane connector 208b and board mount connector 210c portion of backplane connector 208c, connects to backplane connector 208d via cables from cable-to-board connector 214a to cable connector 212d portion of backplane connector 208d, and connects to backplane connector 208e via cables from cable-to-board connector 214b to cable connector 212e portion of backplane connector 208e. Further, in one embodiment, ASIC 202b connects to backplane connector 208b via cables from cable-to-board connector 214d to cable connector 212b portion of backplane connector 208b, connects to backplane connector 208c via cables from cable-to-board connector 214e to cable connector 212c portion of backplane connector 208c, and connects via traces to board mount connector 210d portion of backplane connector 208d and board mount connector 210e portion of backplane connector 208e.

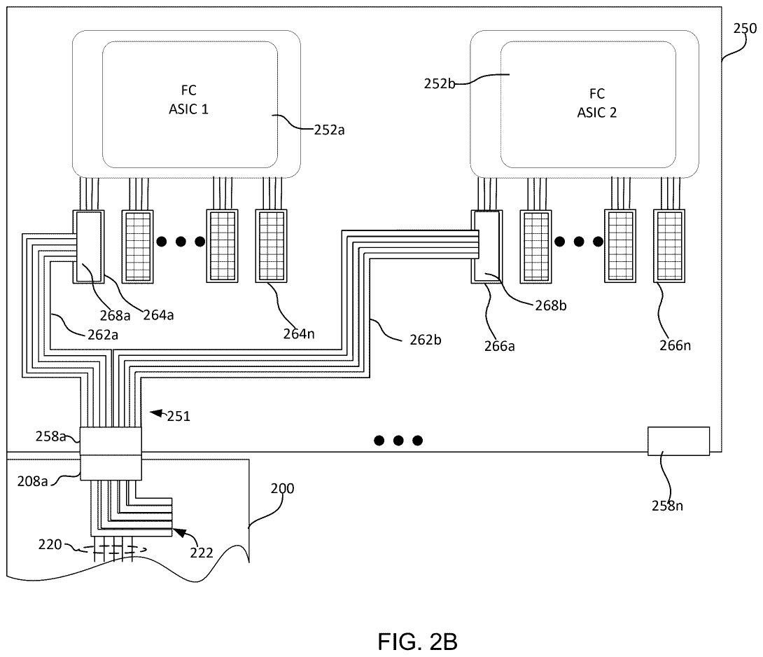

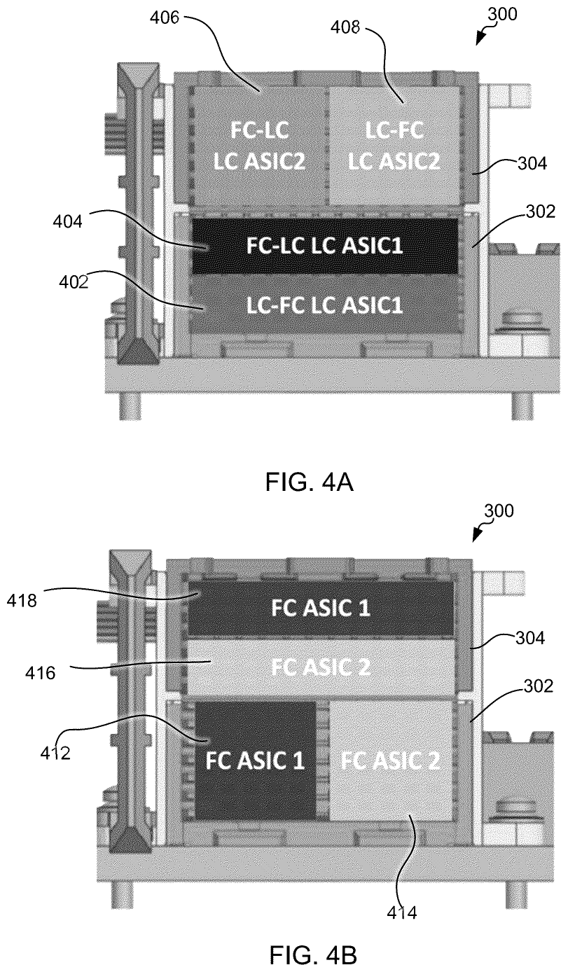

In one embodiment, one or more of the hybrid connectors has a stacked configuration in which the cable connector is to the opposite side of the board mount connector. Using the example of backplane connector 208a, in one example of such an arrangement, board mount connector 210a is mounted to PCB 201 and cable connector 212a is mounted to the side of board mount connector away from PCB 201. One non-limiting example of a stacked configuration is illustrated in FIG. 3. In another embodiment, one or more hybrid connectors has a side-by-side arrangement in which the cable connector is positioned next to the board mount connector along the PCB. Using the example of backplane connector 208a, in one example of such an arrangement, board mount connector 210a is mounted to PCB 201 and cable connector 212a is mounted next to board mount connector along PCB 201. One embodiment of a side-by-side configuration is illustrated in FIG. 6. Regardless, a hybrid connector can act as a single connector such that a mating connector can mate across the board mount connector and cable connector as if they are single connector.

Line card 200 is one illustrative embodiment of a network device that incorporates one or more hybrid connectors. Hybrid connectors, however, may be used in a variety of computing devices including, but not limited to, line cards that include a different number of front-end ports, backplane connectors, switching processors, etc. than illustrated in FIG. 2A. Further, while fabric ASIC 202a and fabric ASIC 202b are illustrated in a side-by-side configuration, other embodiments may use other configurations. According to one embodiment, the switching processors are mounted to PCBs having a back-to-back arrangement.

FIG. 2B is a diagrammatic representation of embodiment of a fabric card 250, which may be used, for example as an FC 102, in one embodiment. FC 250 includes fabric ASIC 252a and fabric ASIC 252b. FC 250 includes n LC mating connectors (e.g., mating connector 258a . . . mating connector 258n) to mate with a respective backplane connector of an LC (e.g., LC mating connector 258a is illustrated as connected to backplane connector 208a of an LC 200). According to one embodiment, FC 250 can connect to multiple LCs with, for example, each LC mating connector connecting to a backplane connector of a different LC.

When LC 200 is connected to FC 250 signal paths are formed through backplane connector 208a and mating connector 258a that connect switching ASICs 202a, 202b to fabric ASICs 252a, 252b. The signal paths from the mating connector 258a are divided between the fabric ASICs according to a desired load balancing scheme. For instance, in one embodiment, the signal paths are evenly divided between the fabric ASICs such that in a two fabric ASIC embodiment, as illustrated in FIG. 2B, half the signal paths connect to fabric ASIC 252a and half the signal paths connect to fabric ASIC 252b. According to one embodiment, there are an equal number of signal paths for forwarding traffic between the first fabric ASIC 252a and the first switching ASIC 202a, the first fabric ASIC 252a and the second switching ASIC 202b, the second fabric ASIC 252b and the first switching ASIC 202a, and the second fabric ASIC 252b and the second switching ASIC 202b.

According to one embodiment, the LC mating connectors are cable connectors that terminate cable harnesses where cable harnesses connect signal paths from the backplane connectors to the fabric ASICs. To this end, FC 250 includes cable-to-board connectors 264a through 264n which are connected to ASIC 252a (e.g., via board traces) and cable-to-board connectors 266a through 266n which are connected to ASIC 252b (e.g., via board traces) to allow a cable harness to be used to connect signal paths each fabric ASIC. The cables of a cable harness can be segregated between the components to achieve the desired load balancing.

According to one embodiment, for example, FC 250 includes a cable harness that comprises mating connector 258a, low insertion loss cables 262a that run from mating connector 258a to cable-to-board connector 268a and low insertion loss cables 262b that run from mating connector 258a to cable-to-board connector 268b. Cable-to-board connector 268a mates with connector 264a to connect signal paths from backplane connector 208a to fabric ASIC 252a and cable-to-board connector 268b mates with connector 266a to connect signal paths from backplane connector 208a to fabric ASIC 252b. Similarly, cable harnesses may connect between other LC backplane connectors and each of the fabric ASICs.

Fabric card 250 is one illustrative embodiment of a network device. A fabric card may have a different number of connectors, fabric processors, etc. than illustrated in FIG. 2B. Further, while fabric ASIC 252a and fabric ASIC 252b are illustrated in a side-by-side configuration, other embodiments may use other configurations. According to one embodiment, the fabric processors may be mounted to PCBs having a back-to-back arrangement.

FIG. 3A, FIG. 3B and FIG. 3C (collectively FIG. 3) are diagrammatic representations of one embodiment of a hybrid connector 300 that includes a board mount connector 302 and a cable connector 304 stacked thereon. Various techniques can be used for mounting board mount connector 302 to a PCB, such as surface mount technologies, compression contacts, press fit pins, solder tails, or other techniques. According to one embodiment, board mount connector 302 is a lead frame connector. Cable connector 304 is a connector that terminates signal cables and, even more particularly, low insertion loss cables.

Board mount connector 302 includes an insulative board mount connector housing 303 that defines a front end and a back end and supports a plurality of mating interface signal contacts. Board mounted connector 302 includes an array of board mount signal contacts (e.g., pads, pins, balls, solderless compression contacts, solder tails or other board mount features) on its board mount side 306 (the face that faces PCB 350) and can be mounted to a PCB (e.g., PCB 350). Board traces provide signal paths from other components of a computing system to board mount connector 302. In one embodiment, the board traces connect between board mount connector 302 and a network processor, such as a switching ASIC or another type of network processor.

The back end of board mount connector 302 comprises a mating interface 308 for mating with one or more complementary connectors (e.g., non-board mount connectors). In one embodiment, mating interface 308 is configured to mate with one or more cable connectors where each mating cable connector terminates one or more cables (e.g., one or more low insertion loss cables, such as twinax cables).

Mating interface 308 comprises a pattern (e.g., an array) of contact areas with each contact area including one or more mating interface signal contacts configured to form electrical connections with corresponding contacts of a mating connector. The mating interface signal contacts of a contact area are electrically connected to board mount contacts of board mount connector 302 and are configured to form electrical connections with corresponding contacts of a mating connector contacts. Board mount connector 302 thus connects signal paths between board traces of PCB 350 and the mating connector(s).

Cable connector 304 is mounted to board mount connector 302 away from board mount side 306 and PCB 350. Cable connector 304 comprises a respective housing 312 that can be formed of an insulative material that defines a front end and a back end and supports a plurality of mating interface signal contacts. The front end of housing 312 is configured to receive conductive cables 314 (e.g., low insertion loss cables, such as twinax cables), which are terminated at cable connector 304. In one embodiment, the opposite ends of cables 314 (not shown) terminate at a cable to board connection that is, in turn, connected by traces to a network processor, such as switching ASIC or another type of network processor.

The back end of cable connector 304 comprises a mating interface 316 for mating with one or more complementary connectors. In one embodiment, mating interface 316 is configured to mate with one or more cable connectors where each mating cable connector terminates one or more cables (e.g., one or more low insertion loss cables, such as twinax cables).

Mating interface 316 comprises a pattern (e.g., an array) of contact areas (with each contact area including one or more signal contacts (mating interface signal contacts). The mating interface signal contacts of a contact area are electrically connected to a respective cable 314 and are configured to form electrical connections with corresponding contacts of a mating connector. Board mount connector 302 thus connects signal paths between cables 314 and the mating connector(s).

The overall mating interface of hybrid connector 300 has an (X×Y) connector configuration with X rows by Y columns of contact areas to support up to (X×Y)/2 lanes or (X×Y) diff pairs. The number rows and columns may vary by implementation. For example, cable connector 304 has a 12×10 connector configuration that can support up to 120 diff pairs or 60 data lanes. A given network device, however, may use fewer diff pairs/data lanes than the maximum number supported by the hybrid connector.

Further, the segregation of rows or columns between the board mount connector and the cable connector may vary by implementation. In one embodiment, for example, each cable connector provides (X/2) rows. In FIG. 3, for example, the top six rows are provided by cable connector 304 and the bottom six rows are provided by board mount connector 302 with the columns being split across the connectors. In other embodiments, the rows may be otherwise divided between the cable connector and board mount connector.

According to one embodiment, one or more mating connectors (e.g., press fit connectors) may be mated with hybrid connector 300. Whether one or multiple mating connectors are mated with hybrid connector 300, a given mating connector may span across board mount connector 302 and cable connector 304.

Hybrid connector 300 includes a pair of spaced sidewalls 320, each of which has a respective base 322 (e.g., a flange or other portion to act as a base) and upper member 324 (e.g., flange). Each base 322 includes an opening 326 such that each sidewall 320 may be aligned on a guide pin or attached to the PCB or other support structure using a screw or other fastener. Each upper member 324 includes an opening 328 such that a cover may be aligned on hybrid connector 300 (e.g., using guide pins on the cover) or attached to the sidewalls using screws or other fasteners. Upper members 324 further include alignment features, such as alignment pins 330, to aid in aligning a cover over hybrid connector 300.

One or more of the sidewalls 320 may include or be coupled to a rearwardly extending panel 332 that extends past mating interface 308 or mating interface 316. In one embodiment, panel 332 includes guide features 334 projecting from panel 332, to help align a mating connector with hybrid connector 300. A mating connector may include one or more grooves to receive guide features 334 such that the mating connector is guided along a mating axis as it is being connected to hybrid connector 300.

With reference to FIG. 3C, hybrid connector 300 includes guide features to guide board mount connector 302 and cable connector 304 into position during assembly. For example, at least one of the sidewalls 320 comprises an inward projection, the board mount connector defines a first slot into which the inward projection projects and the cable connector defines a second slot into which the inward projection projects. In the illustrated embodiment, for example, the inner surface of each sidewall 320 includes a vertically elongated guide projection 340, the sides of housing 303 includes slots 342 (only one slot 342 is visible in FIG. 3C) to receive guide projections 340 and housing 312 includes respective slots 344 (only one slot 344 is visible in FIG. 3C) to receive the guide projections 340. The guide projections 340 on the inner surfaces of sidewalls 320 and respective slots in the side surfaces of housing 303 form a prismatic joint that allows board mount connector 302 to slide into position on PCB 350 during assembly. Similarly, the guide protrusions on the inner surfaces of sidewalls 320 and respective slots in the side surfaces of housing 303 form a prismatic joint that allows cable connector 304 to slide into place on top of board mount connector 302. Alignment pins 346 are provided on housing 303 and extend into holes 348 of housing 312 when cable connector 304 is properly stacked on board mount connector 302.

According to one embodiment, sidewalls 320 are installed on a PCB. Board mount connector 302 is guided to a location on PCB using guide projections 340 and assembled to the PCB with board mount technology. Cable connector 304 is guided into place by guide projections 340 and tightly assembled to act as a single connector. In one embodiment, for example, PCB 350, sidewalls 320, and a cover surround the stacked board mount connector 302 and cable connector 304 on the top, bottom, and sides. Guide projections 340 and alignment pins 346 prevent cable connector 304 from moving back or forward relative to board mount connector 302. Hybrid connector 300 acts as a single connector such that a mating connector can mate to hybrid connector 300 across board mount connector 302 and cable connector 304 as if they are single connector. Thus, for example, a mating cable connector can be connected to hybrid connector 300 where a portion of the mating cable connector mates with board mount connector 302 and another portion mates with cable connector 304 as if hybrid connector 300 is a single connector.

When installed on a board, board mount connector 302 is connected to one or more other components, such as a switching ASIC or another type of processor, via traces embedded in the PCB. Moreover, cable connector 304 is connected to one or more components of the system via cables. For example, cables may be connected between cable connector 304 and a cable-to-board connector to connect signal paths between cable connector 304 and an ASIC or other processor.

In the embodiment of FIG. 3, board mount connector 302 and cable connector 304 are each formed as a separate connector and then assembled into a hybrid connector that acts as a single connector. The embodiment of FIG. 3 further provides the ability to disassemble the connector. Thus, for example, if cable connector 304 is to be replaced (e.g., due to damage or for any other reason), it may be non-destructively removed (i.e., without damaging board mount connector 302, requiring breaking of adhesive or other bonding agent between cable connector 304 and board mount connector 302, etc.) and replaced without having to remove and replace board mount connector 302. Similarly, if board mount connector 302 is damaged or otherwise requires replacement, it may be replaced without requiring a replacement cable connector 304.

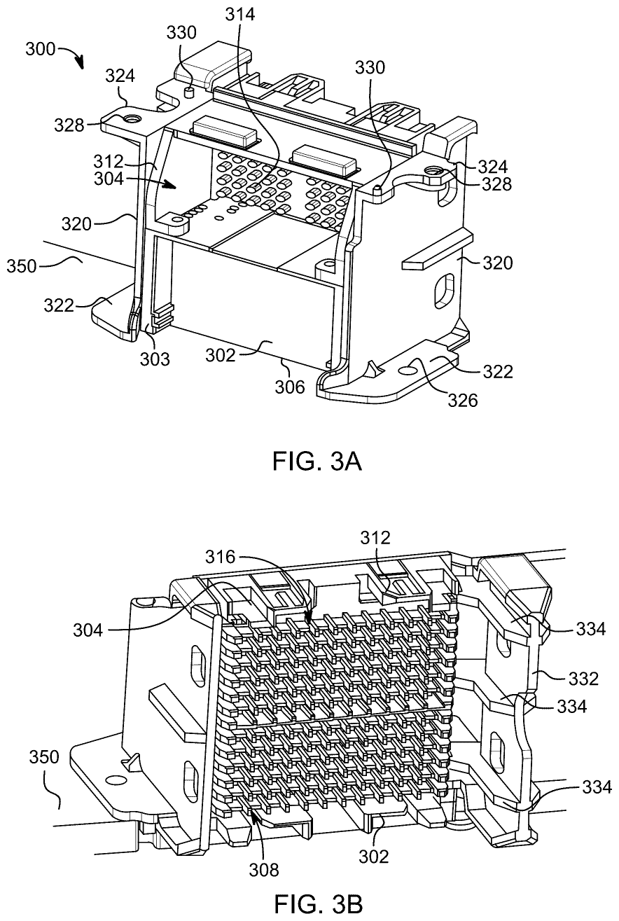

FIG. 4A and FIG. 4B illustrate an example configuration for load balancing using a 12×10 hybrid connector 300 in an embodiment in which there are two switching ASICs on a line card and two fabric ASICs in a fabric card. In this example, the hybrid connector includes 120 diff pairs (supports 60 data lanes). A given network device, however, may use fewer diff pairs/data lanes than the maximum number supported by the hybrid connector.

In the example of FIG. 4A, the first six rows provided by board mount connector 302 connect to a first switching ASIC of the line card using board traces and the second six rows provided by cable connector 304 connect to the second switching ASIC via low insertion loss cables. Further, in the embodiment illustrated, the first three rows (region 402) are for signals from the first switching ASIC to the fabric card while the second three rows (region 404) carry signals from the fabric card to the first switching ASIC. For the six rows provided by cable connector 304, the first five columns (region 406) are used for signals from the fabric card to the first switching ASIC and the other five columns (region 408) are used for signals from the fabric card to the second switching ASIC.

FIG. 4B illustrates an example allocation of signal paths to fabric ASICs. In this example, the first six rows provided by board mount connector 302 are split with the first five columns (region 412) connected via the mating interface and respective connections (e.g., low insertion loss cables) to a first fabric ASIC and the second five columns (region 414) connected via the mating interface and respective connections to the second fabric ASIC. The second six rows provided by cable connector 304 are split with the first three rows (region 416) connected via the mating interface and respective connections (e.g., low insertion loss cables) to the second fabric ASIC and the other three rows (region 418) connected via the mating interface and respective connections (e.g., low insertion loss cables) to the first fabric ASIC.

Using an example embodiment in which backplane connector 208a of FIG. 2A and FIG. 2B is a hybrid connector 300 and using the example allocations of FIG. 4A and FIG. 4B, the six rows provided by board mount connector 210a connect to switching ASIC 202a via traces 220 and the six rows provided by cable connector 212a connect via low insertion loss cables 222 that run between cable-to-board connector 214c and cable connector 212a. Further in this example embodiment, the first five columns of the first six rows (region 412) and the second three rows of the cable connector (region 418) are connected to fabric ASIC 252a via the mating connector 258a and respective low insertion loss cables 262a that run from mating connector 258a to cable-to-board connector 264a, while the next five columns of the first six rows (region 414) and the first three rows provided by the cable connector (region 416) are connected to fabric ASIC 252b via the mating connector 258a and respective low insertion loss cables 262b that run from mating connector 258a to cable-to-board connector 266a.

In this example:
i) the first five columns of the first three rows (overlap of region 402 and region 412) are used for signals from switching ASIC 202a to fabric ASIC 252a;
ii) the first five columns of the second three rows (overlap of region 404 and region 412) are used for signals from fabric ASIC 252a to switching ASIC 202a;
iii) the second five columns of the first three rows (overlap of region 402 and region 414) are used for signals from switching ASIC 202a to fabric ASIC 252b;
iv) the second five columns of the second three rows (overlap of region 404 and region 414) are used for signals from fabric ASIC 252b to switching ASIC 202a;
v) the first five columns of the third three rows (overlap of region 406 and region 416) are used for signals from fabric ASIC 252b to switching ASIC 202b;
vi) the first five columns of the fourth three rows (overlap of region 406 and region 418) are used for signals from fabric ASIC 252a to switching ASIC 202b;
vii) the second five columns of the third three rows (overlap of region 408 and region 416) are used for signals from switching ASIC 202 b to fabric ASIC 252b; and
viii) the second five columns of the fourth three rows (overlap of region 408 and region 418) are used for signals from switching ASIC 202b to fabric ASIC 252a.

In some embodiments, the hybrid connector supports more diff pairs/data lanes than are used. In any case, the diff pairs/data lanes to/from the switching ASICS from/to the fabric ASICs can be equally balanced with the same number of data lanes between ASIC 202a and fabric ASIC 252a, ASIC 202a and fabric ASIC 252b, ASIC 202b and fabric ASIC 252a, and ASIC 202b and fabric ASIC 252b. FIG. 4A and FIG. 4B are provided by way of example and other examples of allocating signal paths may be used to achieve a desired load balancing.

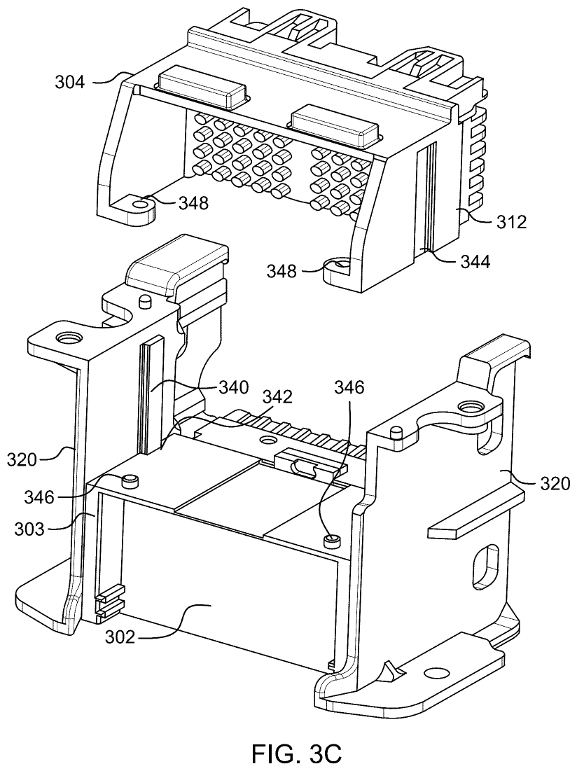

FIG. 5 illustrates one embodiment of a cable harness 500 for connecting components to a hybrid connector. Cable harness 500 may be one embodiment of cable harness 251. Cable harness 500, according to one embodiment, implements the mapping of FIG. 4B for load balancing. According to one embodiment, cable harness 500 includes a mating connector 502 having a mating interface compatible with the mating interface of a hybrid connector 300. The mating interface comprises a pattern (e.g., an array) of contact areas with each contact area including one or more mating interface signal contacts configured to form electrical connections with corresponding contacts of a hybrid connector.

In the embodiment of FIG. 5, mating connector 502 is a cable connector such that the mating interface signal contacts connect to low insertion loss cables. In the embodiment of FIG. 5, a first set of cables 510 connect from first mating interface signal contacts of mating connector 502 and run from mating connector 502 to connector 512 and a second set of cables 520 connect to second mating interface signal contacts of mating connector 502 and run from mating connector 502 to connector 522. According to one embodiment, first set of cables 510 includes cables 514 that connect to the mating interface signal contacts of mating connector 502 that form electrical connections with corresponding contacts of region 412 of hybrid connector 300 and cables 516 that connect to the mating interface signal contacts of mating connector 502 that form electrical connections with corresponding contacts of region 418 of hybrid connector 300 and second set of cables 520 includes cables 524 that connect to the mating interface signal contacts of mating connector 502 that form electrical connections with corresponding contacts of region 412 of hybrid connector 300 and cables 526 that connect to the mating interface signal contacts of mating connector 502 that form electrical connections with corresponding contacts of region 418 of hybrid connector 300. According to one embodiment, connector 512 and connector 522 are cable-to-board connectors compatible with terminal blocks on a PCB. For example, connector 512 may be compatible with connector 264a of FIG. 2B and connector 522 may be compatible with cable-to-board connector 266a of FIG. 2B to create signal paths from the hybrid connector to the fabric card ASICs.

While connector 300 is illustrated as having a stacked arrangement in which board mount connector 302 is mounted to the PCB and cable connector 304 stacks on board mount connector 302 on the side of board mount connector 302 away from the PCB. In other embodiments, the hybrid connector can be otherwise arranged. FIG. 6, for example, is a diagrammatic representation of a hybrid connector 600 comprising a board mount connector 602 and a cable connector 604. In the embodiment illustrated, board mount connector 602 mounts to PCB 605 using surface mount technologies, compression contacts, press fit pins, solder tails, or other board mounting techniques and is connected to other components (e.g., a switching ASIC or other processor) via board traces. Cable connector 604 connects to other components via a cabled connection. Using hybrid connector 600 with the example architecture of FIG. 2A, board mount connector 602 of a hybrid connector 600 connects to the nearest ASIC via board traces and the cable connector 604 portion of hybrid connector 600 connects to the ASIC that is farther away via a cabled connection, though other schemes for connecting signal paths may be used.

Board mount connector 602 and cable connector are assembled to act as a single connector such that a mating connector can mate across the board mount connector and cable connector as if they are single connector. According to one embodiment, hybrid connector 600 provides (X×Y) connector configuration with X rows by Y columns where board mount connector provides a first number of columns and cable connector provides the remaining columns with the rows being split across the board mount connector 602 and cable connector 604.

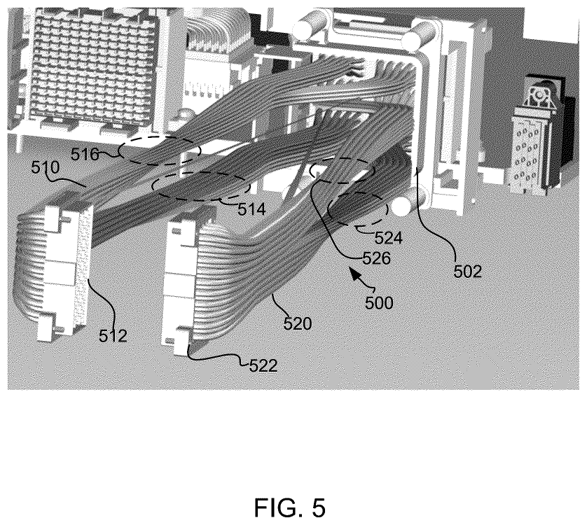

FIG. 7 is a diagrammatic representation of one embodiment of a hybrid connector 700 that comprises a board mount connector 702 and a cable connector 704 in a stacked arrangement. Board mount connector 702 is mounted to PCB 706 such that the board mount signal contacts (e.g., pads, pins, balls, solderless compression contacts, solder tails or other board mount features) connect to traces of PCB 706. Board mount connector 702 comprises electrical connections (e.g., high speed signal pins) connecting the board mount signal contacts to mating interface signal contacts (e.g., board mount signal contact 708 is electrically connected to mating interface signal contact 710 by connection 712). At cable connector 704, the conductors of the signaling cables are electrically connected to mating interface signal contacts (e.g., a conductor 722 of cable 720 is electrically connected to mating interface signal contacts). For a cable with multiple conductors, such as a twinax cable, each conductor may be connected to a respective mating interface signal contact in some embodiments.

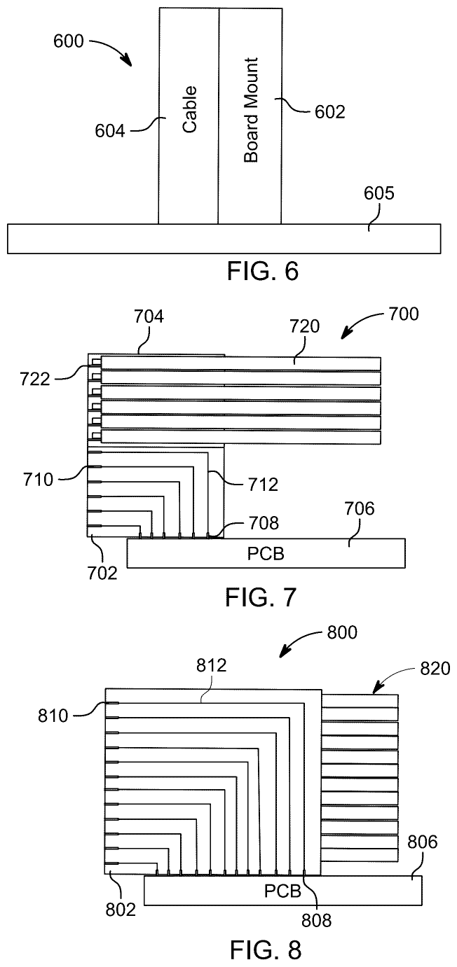

FIG. 8 is a diagrammatic representation of one embodiment of a hybrid connector 800 that comprises a board mount connector 802 and a cable connector in a side-by-side arrangement (the cable connector is hidden by board mount connector 802 in FIG. 7). Board mount connector 802 is mounted to PCB 806 such that the board mount signal contacts (e.g., pads, pins, balls, solderless compression contacts, solder tails or other board mount features) connect to traces of PCB 806. Board mount connector 802 comprises electrical connections (e.g., high speed signal pins) connecting the board mount signal contacts to mating interface signal contacts (e.g., board mount signal contact 808 is electrically connected to mating interface signal contact 810 by connection 812). At the cable connector, the conductors of the signaling cables 820 are electrically connected to mating interface signal contacts.

Comparing FIG. 7 to FIG. 8, it can be noted that the longest internal signal path lengths of hybrid connector 800 (e.g., connection 812) is longer than the longest internal signal path length of hybrid connector 700 (e.g., connection 712). The stacked arrangement of hybrid connector 700 results in a lower insertion loss and a smaller connector footprint on the board compared to hybrid connector 800.

FIG. 7 and FIG. 8 are provided by way of example and not limitation. The number of rows in the board mount connector and cable connector may vary by implementation. Moreover, the internal routing of connections is simply illustrative.

As discussed above, some embodiments of the present disclosure may use a back-to-back arrangement of PCBs to which processors (e.g., network processors) are mounted using ball grid array (BGA) packaging or other board mount packaging or other mounting technology. The processors, in some embodiments, comprise fabric processors (e.g., fabric ASICs or other fabric processors) or switching processors (e.g., switching ASICs or other switching processors).

The PCBs in the “back-to-back” arrangement are spaced apart with their front sides—that is, the sides to which the network processors are mounted—facing opposite directions. This arrangement can use PCBs that are smaller than would be required to support the same number and type(s) of network processors on a single PCB and facilitates the use of signal channels that meet the insertion loss requirements of components while reducing or eliminating the need for repeater devices, such as retimers.

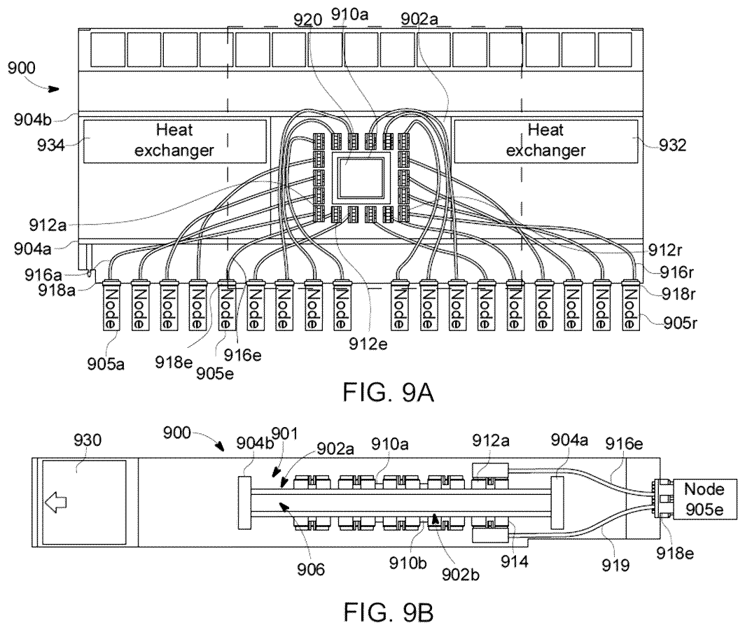

FIG. 9A is a diagrammatic representation of a network device 900 and FIG. 9B is a diagrammatic representation of a second view of network device 900 (FIG. 9A and FIG. 9B are referred to collectively herein as FIG. 9). Certain features or omitted from FIG. 9B for clarity.

Network device 900 includes a “back-to-back” arrangement 901 of PCBs that includes PCB 902a and PCB 902b. Each of PCB 901 has a front side (the “front side” of a PCB is also referred to as the “component side” or “primary side”) and a rear side. According to one embodiment, PCB 902a and PCB 902b are identical PCBs. PCB 902a and PCB 902b are mounted to a common frame structure that comprises rail 904a and rail 904b and are spaced by a gap 906. In some embodiments, gap 906 is an air gap.

A network processor 910a is mounted to the front side of PCB 902a and a network processor 910b is mounted to the front side of PCB 902b using BGA packaging or other surface mount packaging or other mounting technology. According to one embodiment, each of network processor 910a and network processor 910b is a network ASIC, such as a switching ASIC or a fabric ASIC, that handles traffic forwarding and can provide other traffic management functionality.

Network processor 910a and network processor 910b of the back-to-back arrangement are connected to nodes 905a-905r (node 905a, node 905e and node 905r are indicated) by respective signal channels. Network processor 910a and network processor 910b provide traffic forwarding capability to forward traffic between the nodes. Examples of nodes include line cards, network ports, or other types of connected components between which traffic can be forwarded by the network processors.

The signal channels between network processors and nodes 905a-905r comprise traces, signal channel cables, connectors or other components or combinations thereof to form electrical paths from the network processors to the nodes. PCB 902a, for example, includes cable-to-board connectors 912a-912r (e.g., terminal blocks) which are electrically connected to network processor 910a by traces (board-to-cable connector 912a, board-to-cable connector 912e, and board-to-cable connector 912r are indicated in FIG. 9A; board-to-cable connector 912e is hidden by board-to-cable connector 912a in FIG. 9B). PCB 902b similarly includes board-to-cable connectors that are electrically connected to network processor 910b by traces (board-to-cable connector 914 is indicated in FIG. 9B). In the embodiment of FIG. 9, the board-to-cable connectors are arranged about the four sides of the respective network processor. This arrangement provides flexibility in signal channel cable routing and allows the signal channel cables to be fanned out to minimize their effect on air flow.

Signal channel cables connect between the board-to-cable connectors and node connectors 918a-918r. For PCB 902a, signal channel cables 916a-916r, such as twinax signal channel cables, connect between the board-to-cable connectors 912a-912r and node connectors 918a-918r (e.g., signal channel cable 916a connects between board-to-cable connector 912a and node connector 918a, signal channel cable 916e connects between board-to-cable connector 912e and node connector 918e, signal channel cable 916r connects between board-to-cable connector 912r and node connector 918r). Similarly, signal channel cables connect between the board-to-cable connectors of PCB 902b and the node connectors 918a-918r (e.g., signal channel cable 919 connects between a signal channel cable connector of PCB 902b and node connector 918e in FIG. 1B). According to one embodiment, node connectors 918a-918r are near package connectors (NPCs). In one embodiment, node connectors 918a-918r are mating connectors that connect to hybrid connectors.

In the embodiment of FIG. 9 the node connectors 918a-918r and nodes 905a-905r are arranged in a row, spaced from the edges of the PCBs 902a, 902b so that, for example, each node connector 918a-918r or node 905a-905r is, from a signal path perspective, approximately equidistant from network processor 910a and network processor 910b. As such, the lengths of the signal channels from network processor 910a to a node connector 918a-918r or node 905a-905r is approximately the same as the length of the signal path from network processor 910b to the same node connector 918a-918r or node 905a-905r.

The signal channels between network processor 910a or network processor 910b and node 905a-905r are configured to satisfy the insertion loss requirements of the respective network processor and node. Using the example of the signal channel between network processor 910a and node 905a, i) network processor 910a has an associated insertion loss and insertion loss specification; and ii) node 905a has an associated insertion loss and insertion loss specification. With respect to node 905a, for example, the node may include a node processor (e.g., a node ASIC) that has an associated assertion loss and insertion loss specification. Further node 905a may have an insertion loss for the portion of the signal channel between the node connection and the node processor.

Given the insertion loss of network processor 910a and the insertion loss of node 905a, an insertion loss requirement (allowable insertion loss) for the signal channel from network processor 910a to node 905a can be determined so that the total insertion loss of the complete channel between network processor 910a to node 905a satisfies the insertion loss specifications of the network processor 910a and node 905a. The components and arrangement of a signal channel can thus be selected so that the signal channel satisfies the insertion loss requirements of network processor 910a and node 905a. For example, signal channel cable 916a, connector 912a, connector 918a, and traces can be selected so that the signal channel meets the insertion loss requirement.

A heat sink is coupled to the front surface of each of the network processors (e.g., heat sink 920 is coupled to network processor 910a) and is adapted to conduct heat away from the network processors. According to one embodiment, heat exchangers (e.g., heat exchanger 932, heat exchanger 934) are coupled to the heat sinks to further enhance heat management. Network device 900 includes fans 930 to produce airflow over and between the PCBs and to carry heat away from the heat sinks and heat exchangers.

Network device 900 is merely illustrated and embodiments of network devices are scalable and can include more or fewer network processors, node connectors, etc.

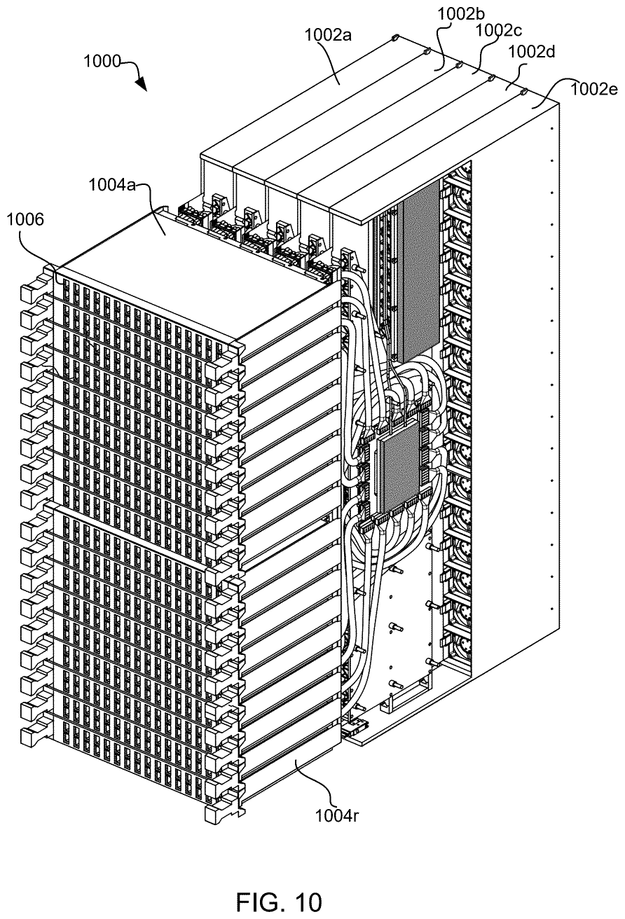

FIG. 10 is a diagrammatic representation of one embodiment of a modular network device 1000 that incorporates hybrid connectors and a back-to-back PCB arrangement. Network device 1000 includes a plurality of fabric cards (fabric card 1002a, fabric card 1002b, fabric card 1002c, fabric card 1002d, fabric card 1002e) connected to a plurality of line cards 1004a-1004r. The line cards 1004a-1004r provide front-end ports for network connections (e.g., front-end port 1006 is indicated). In one embodiment, each line card 1004a-1004r includes a plurality of switching ASICs for forwarding traffic between ports of that line card and traffic to/from the fabric cards and each fabric card 1002a-1002e includes a plurality of fabric ASICs for transferring traffic between line cards 1004a-1004r. Network device 1000 is merely illustrative and embodiments of modular network devices are scalable and can include more or fewer fabric cards, line cards, network processors, etc.

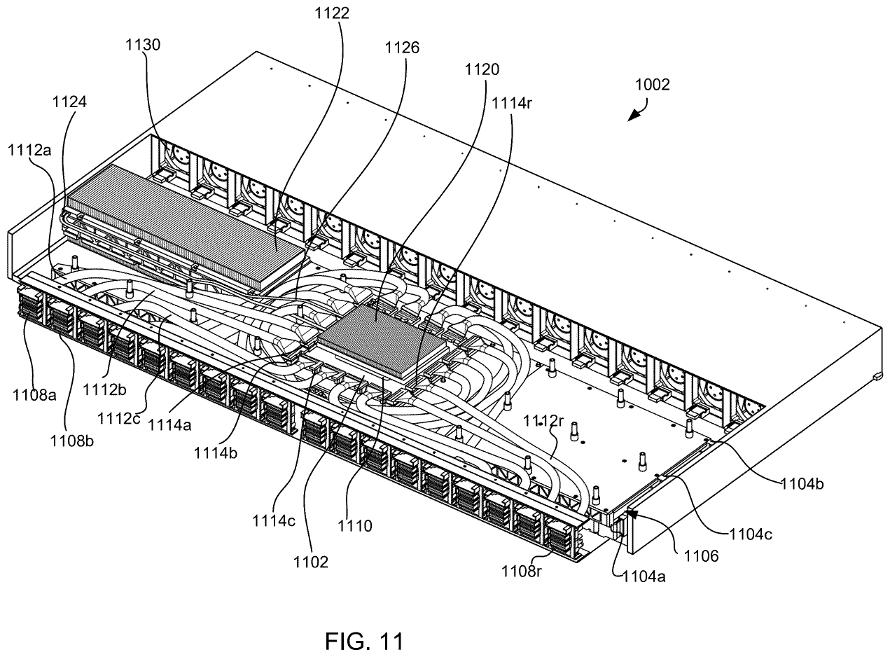

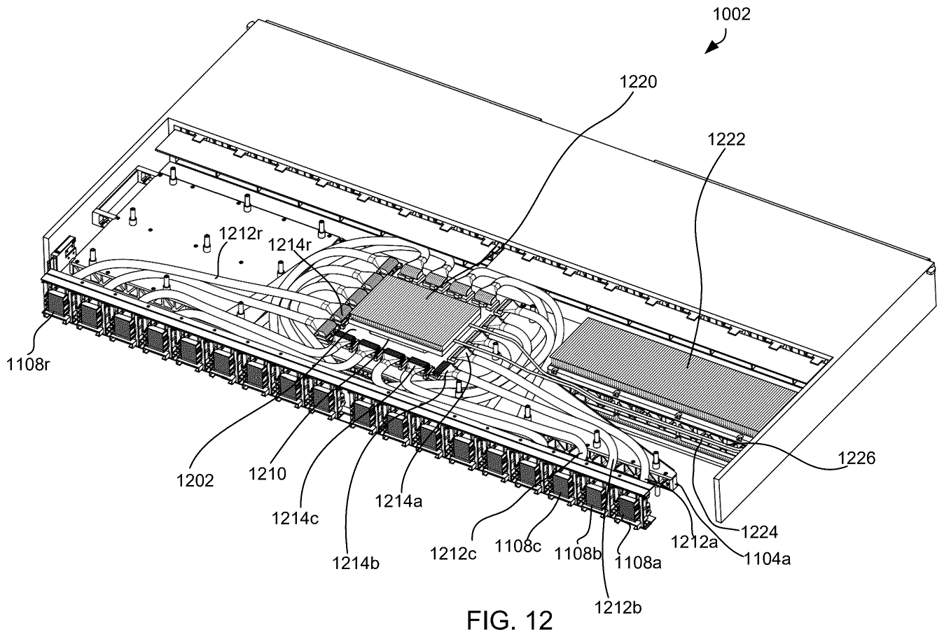

FIG. 11 is a diagrammatic representation of a first view of one embodiment of a fabric card 1002 (e.g., fabric card 1002a, fabric card 1002b, fabric card 1002c, fabric card 1002d, or fabric card 1002e) and FIG. 12 is diagrammatic representation of a second view of one embodiment of fabric card 1002.

Fabric card 1002 includes a “back-to-back” arrangement of PCBs that includes PCB 1102 and PCB 1202. A network processor 1110 is mounted to the front side of PCB 1102 and a network processor 1210 is mounted to the front side of PCB 1202 using BGA packaging or other surface mount packaging or other mounting technology. According to one embodiment, network processor 1110 and network processor 1210 are fabric processors, such as, but not limited to, fabric ASICs.

PCB 1102 and PCB 1202 are coupled to a common frame structure that includes rail 1104a, rail 1104b and rail 1104c. The common frame structure provides attachment holes for various components, such as PCBs, NPCs, or other components. Between the rails, PCB 1102 and PCB 1202 are separated by a gap 1106. In some embodiments, gap 1106 is an air gap.

Fabric card 1002 includes a row of NPCs 1108a-1108r for connecting to line cards 1004a-1004r. NPCs 1108a-1108r are arranged in a row, spaced from the edge of PCB 1102 and PCB 1202, with each NPC 1108a-1108r positioned, from a signal path perspective, approximately equidistant from network processor 1110 and network processor 1210. As such, the lengths of the signal channels from network processor 1110 to an NPC 1108a-1108r is approximately the same as the length of the signal path from network processor 1210 to the same NPC 1108a-1108r.

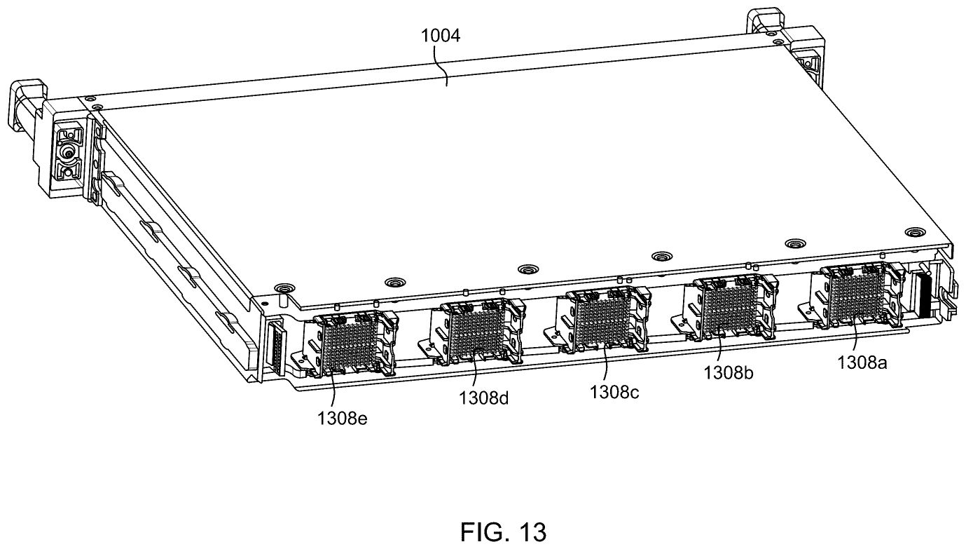

The network processors of fabric card 1002 are connected to NPCs 1108a-1108r by respective signal channels (NPC 1108a, NPC 1108b, NPC 1108c, and NPC 1108r are indicated). The signal channels between the network processors and NPCs 1108a-1108r comprise traces, signal channel cables, connectors or other components or combinations thereof to form electrical paths from the network processors to the nodes. PCB 1102, for example, includes board-to-cable connectors 1114a-1114r (board-to-cable connector 1114a, board-to-cable connector 1114b, board-to-cable connector 1114c, and board-to-cable connector 1114r are indicated in FIG. 12), which are electrically connected to network processor 1110 by traces of PCB 1102 and to NPCs 1108a-1108r by respective signal channel cables 1112a-1112r (signal channel cable 1112a, signal channel cable 1112b, signal channel cable 1112c, and signal channel cable harness 1112r are indicated in FIG. 11, each signal channel cable 1112a-1112r may comprise a bundle of cables or other connections or otherwise support multiple signal channels). Similarly, PCB 1202 includes board-to-cable connectors 1214a-1214r (board-to-cable connector 1214a, board-to-cable connector 1214b, board-to-cable connector 1214c, and board-to-cable connector 1214r are indicated in FIG. 13), which are electrically connected to network processor 1210 by traces of PCB 1202 and to NPCs 1108a-1108r by respective signal channel cable 1212a-1212r (signal channel cable 1212a, signal channel cable 1212b, signal channel cable 1212c, and signal channel cable 1212r are indicated, each signal channel cable 1212a-1212r may comprise may comprise a bundle of cables or other connections or otherwise support multiple signal channels). According to one embodiment, signal channel cables 1112a-1112r and signal channel cables 1212a-1212r comprises multiple twinax cables.

In the embodiment of fabric card 1002 illustrated in FIG. 11 and FIG. 12, the board-to-cable connectors are arranged about the four sides of the respective network processor. This arrangement provides flexibility in signal channel cable routing and allows signal channel cables 1112a-1112r and signal channel cables 1212a-1212r to be fanned out to minimize their effect on air flow.

The line cards 1004a-1004r (FIG. 10) that connect to fabric card 1002 by NPC 1108a-1108r may use network processors, such switching ASICs, that have a known insertion loss and insertion loss specifications. In addition, the line cards 1004a-1004r may have additional known insertion losses, such as those caused by a signal channel portion internal to the line card. Further, network processor 1110 and network processor 1210 may have an insertion loss specification and a known insertion loss.

Given the insertion losses of network processor 1110, network processor 1210, and line cards 1004a-1004r, an insertion loss requirement (allowable insertion loss) for the signal channels from network processor 1110 and network processor 1210 to the line card 1004a-1004r can be determined so that the total insertion loss of a complete channel between network processor 1110 or network processor 1210 to the network processor of the line card 1004a-1004r satisfies the insertion loss specifications of the network processor and node processor. The components and arrangement of the signal channels can thus be selected so that each signal channel satisfies the insertion loss requirements of the respective network processor 1110 or network processor 1210 and line card 1004a-1004r. For example, the traces of PCB 1102 and PCB 1202, signal channel cables 1112a-1112r, signal channel cables 1212a-1212r, board-to-cable connectors 1114a-1114r, board-to-cable connectors 1214a-1214r, NPCs 1108a-1108r, backend connectors, traces from hybrid connectors to switching ASICs, cable harnesses from hybrid connectors to switching ASICs can be selected so that the signal channels between network processor 1110 and the switching ASICs of the line card and the signal channels between network processor 1210 and the switching ASICs of the line card meet the insertion loss requirement.

Embodiments may include various heat management features, such as fans, heat transfer devices, etc. In the embodiment of FIG. 11 and FIG. 12, a heat sink 1120 is coupled to network processor 1110 to transfer heat away from network processor 1110 and a heat sink 1220 is coupled to network processor 1210 to transfer heat away from network processor 1210. Heat sink 1120 is coupled to a heat exchanger 1122 by heat pipe 1124 and heat pipe 1126 for the circulation of a cooling fluid (e.g., air, a liquid coolant) to remove heat from heat sink 1120. Similarly, heat sink 1220 is coupled to a heat exchanger 1222 by heat pipe 1224 and heat pipe 1226 for the circulation of a cooling fluid to remove heat from heat sink 1220. In one embodiment, heat exchanger 1122 and heat exchanger 1222 are positioned to be above the respective heat sink 1120 and heat sink 1220 during use, as illustrated, for example, in FIG. 10. Thus, heat may be transferred away from heat sink 1120 and heat sink 1220 using a thermal chimney. Fabric card 1002 further comprises fans 1130 to produce airflow over and between the PCBs and to carry heat away from the heat sinks and heat exchangers. As discussed above, the signal channel cables may be routed to minimize impact on air flow, while still satisfying the insertion loss requirements.

Fabric card 1002 is merely illustrative and fabric cards can include a different number of fabric processors per fabric card 102, NPCs, etc. than illustrated in FIG. 11 and FIG. 12. Further, while fabric card 1002 is illustrated as supporting up to eighteen line cards, fabric cards may support more or fewer line cards in various embodiments.

FIG. 13 is a diagrammatic representation of one embodiment of a line card 1004 (e.g., line card 1004a, line card 1004r, etc.), which may be an example of a line card 104 or line card 200 having multiple switching processors. Line card 1004 has five backplane connectors (backplane connector 1308a, backplane connector 1308b, backplane connector 1308c, backplane connector 1308d, backplane connector 1308e) mounted to PCB 1402. Each backplane connector of LC 1004 is a hybrid connector and includes a board mount connector and a cable connector.

In the illustrated embodiment, the backplane connectors are hybrid connectors with a stacked arrangement as illustrated, for example, in FIG. 3. The stacked arrangement of the hybrid connectors saves board space. Using an example in which each of the backplane connector is a 12×10 hybrid connector, the internal PCB and chassis of line card 1004 would be significantly longer if ten side-by-side connectors (e.g., ten 6×10 connectors) were used instead of the five hybrid connectors. This could result in longer trace lengths and corresponding increases in insertion loss or would require additional cabling bulk in the line card. Moreover, the overall size of the modular network device in which the line card is incorporated would have to be larger to accommodate the larger line card.

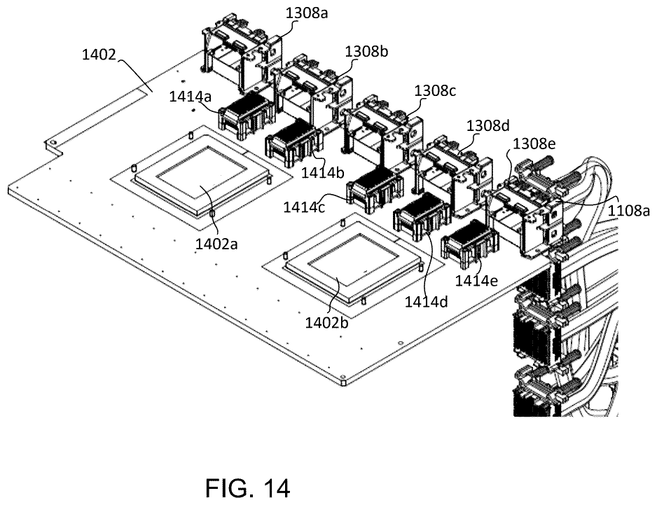

In one embodiment, LC 1004 can connect to multiple fabric cards with, for example, each backplane connector connecting to a different fabric card. According to one embodiment, when a line card 1004 is connected to a fabric card 1002, a hybrid connector of line card 1004 mates with a respective NPC 1108a-1108r of fabric card 1002 to form signal paths between the switching ASICs and the network processors 1110, 1210. FIG. 14, for example, is a diagrammatic representation of a portion of line card 1004 with line card 1004 connected to a fabric card 1002 (e.g., fabric card 1002e). More particularly, backend connector 1308e is connected to NPC 1108a of fabric card 1002.

When line card 1004 is connected to fabric card 1002, there may be a number of signal paths that pass through the respective NPC (e.g., NPC 1108a) and hybrid connector (e.g., backplane connector 1308e) including signal paths between network processor 1110 and switching ASIC 1402a, signal paths between network processor 1110 and switching ASIC 1402b, signal paths between network processor 1210 and the switching ASIC 1402a and signal paths between network processor 1210 and switching ASIC 1402b. The signal paths may be configured to achieve a desired load balancing.

Line card 1004 includes an internal PCB 1402 to which a first switching ASIC 1402a, a second switching ASIC 1402b and the backend connectors are mounted. LC 1004 provides front-end ports (see FIG. 10) that connect to switching ASIC 1402a and switching ASIC 1402b via I/O paths. LC 1004 further includes cable-to-board connector 1414a and cable-to-board connector 1414b connected to ASIC 1402a (e.g., by board traces), and cable-to-board connector 1414c, cable-to-board connector 1414d, and cable-to-board connector 1414d connected to switching ASIC 1402b (e.g., by board traces). According to one embodiment, cable-to-board connector 1414a, cable-to-board connector 1414b, cable-to-board connector 1414c, cable-to-board connector 1414d, cable-to-board connector 1414e are terminal blocks.

According to one embodiment, for each backplane connector, half of the signal paths go to the switching ASIC which is nearer to the connector and the remaining half of the signal paths go to the switching ASIC which is far from the connector. Thus, according to one embodiment, the board mount connector of a hybrid connector connects to the nearest ASIC via board traces and the cable connector portion of the hybrid connector connects to the ASIC that is farther away via a cabled connection, though other schemes for connecting signal paths may be used.

In the embodiment of FIG. 14, switching ASIC 1402a has a short enough route to backplane connector 1308a to be done by board trace. Thus, ASIC 1402a is connected to the board mount connector of backplane connector 1308a via traces and can thus forward and receive traffic through backplane connector 1308a via the traces. ASIC 1402b, on the other hand, has a relatively long route to backplane connector 1308a and can be connected to cable connector portion of backplane connector 1308a via low insertion loss cables that run from the cable connector portion of backplane connector 1308a and connect to cable-to-board connector 1414c.

According to one embodiment, ASIC 1402a further connects via board traces to the board mount connector portion of backplane connector 1308b and the board mount connector portion of backplane connector 1308c, via cables from cable-to-board connector 1414a to the cable connector portion of backplane connector 1308d and via cables from cable-to-board connector 1414b to the cable connector portion of backplane connector 1308e. Further, in one embodiment, ASIC 1402b connects via cables from cable-to-board connector 1414c to the cable connector portion of backplane connector 1308b, via cables from cable-to-board connector 1414e to the cable connector portion of backplane connector 1308c, and via traces to the board mount connector portion of backplane connector 1308d and the board mount connector portion of backplane connector 1308e.

In FIG. 14, backplane connector 1308e is connected to NPC 1108a of a wiring harness. The wiring harness includes cable 1112a that connects signal paths from NPC 1108a to network processor 1110 and cable 1212a that connects signal paths from NPC 1108a to network processor 1210. Thus, with ASIC 1402a and ASIC 1402b connected to backplane connector 1308e, connecting line card 1004 to fabric card 1002 forms signal paths between ASIC 1402a and network processor 1110, ASIC 1402a and network processor 1210, ASIC 1402b and network processor 1110, and ASIC 1402b and network processor 1210.

The signal paths can be configured to achieve a desired load balancing. Applying the mappings of FIG. 4A and FIG. 4B to backplane connector 1308e, regions 402 and 404 correspond to signal paths to switching ASIC 1402b, regions 406 and 408 correspond to signal paths to switching ASIC 1402a, regions 412 and 418 correspond to signal paths to network processor 1110 and regions 414 and 416 correspond to signal paths to network processor 1210. In such an embodiment there are an equal number of signal paths and data lanes between the switching ASIC 1402a and network processor 1110, switching ASIC 1402a and network processor 1210, switching ASIC 1402b and network processor 1110, and switching ASIC 1402b and network processor 1210.

Line card 1004 is one illustrative embodiment of a network device that incorporates one or more hybrid connectors. A line card may have a different number of front-end ports, backplane connectors, switching processors, etc. than illustrated. Further, in some embodiments, the network processors of a line card may be configured in a back-to-back arrangement.

In this disclosure, specific embodiments have been described with reference to the accompanying figures. In the above description, numerous details are set forth as examples. It will be understood by those skilled in the art, and having the benefit of this Detailed Description, that one or more embodiments described herein may be practiced without these specific details and that numerous variations or modifications may be possible without departing from the scope of the embodiments. Certain details known to those of ordinary skill in the art may be omitted to avoid obscuring the description.

In the above description of the figures, any component described with regard to a figure, in various embodiments, may be equivalent to one or more like-named components shown and/or described with regard to any other figure. For brevity, descriptions of these components may not be repeated with regard to each figure. Thus, each and every embodiment of the components of each figure is incorporated by reference and assumed to be optionally present within every other figure having one or more like-named components. Additionally, in accordance with various embodiments described herein, any description of the components of a figure is to be interpreted as an optional embodiment, which may be implemented in addition to, in conjunction with, or in place of the embodiments described with regard to a corresponding like-named component in any other figure.

Throughout the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as by the use of the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

As used herein, the phrase operatively connected, or operative connection, means that there exists between elements/components/devices a direct or indirect connection that allows the elements to interact with one another in some way. For example, the phrase ‘operatively connected’ may refer to any direct (e.g., wired directly between two devices or components) or indirect (e.g., wired and/or wireless connections between any number of devices or components connecting the operatively connected devices) connection. Thus, any path through which information may travel may be considered an operative connection.

While embodiments described herein have been described with respect to a limited number of embodiments, those skilled in the art, having the benefit of this Detailed Description, will appreciate that other embodiments can be devised which do not depart from the scope of embodiments as disclosed herein. Accordingly, the scope of embodiments described herein should be limited only by the attached claims.

What is claimed is:

1. An apparatus, comprising:
first plurality of components mounted to a first printed circuit board (PCB);
a hybrid connector mounted to the PCB and connected to the first plurality of components;
a second plurality of components mounted to a third and fourth PCB in a back-to-back arrangement; and
a plurality of signal paths through the hybrid connector the plurality of signal paths connecting each of the first plurality of components to each of the second plurality of components, the plurality of signal paths load balanced between the first plurality of components and second plurality of components.

2. The apparatus of claim 1, wherein the plurality of signal paths forms an equal number of data lanes between each of the first plurality of components and each of the second plurality of components.

3. The apparatus of claim 1, wherein the first plurality of components is a first plurality of processors and the second plurality of components is a second plurality of processors.

4. The apparatus of claim 3, wherein:
the first plurality of processors comprises:
a first processor; and
a second processor;
the second plurality of processors comprises:
a third processor; and
a fourth processor; and
the plurality of signal paths comprises:
first signal paths between the first processor and the third processor;
second signal paths between the first processor and the fourth process;
third signal paths between the second processor and the third processor; and
fourth signal paths between the second processor and the fourth processor.

5. The apparatus of claim 4, wherein the first processor is a first network processor, the second processor is a second network processor, the third processor is a third network processor, and the fourth processor is a fourth network processor.

6. The apparatus of claim 5, wherein the first network processor is a first switching processor, the second network processor is a second switching processor, the third network processor is a first fabric processor, and the fourth network processor is a second fabric processor.

7. The apparatus of claim 6, wherein the first switching processor is a first switching ASIC, the second switching processor is a second switching ASIC, the first fabric processor is a first fabric ASIC and the second fabric processor is a second fabric ASIC.

8. The apparatus of claim 1, further comprising a cable harness, wherein the cable harness comprises:
a mating connector that interfaces with the hybrid connector; and
a plurality of cables connected to the mating connector, the plurality of cables configured to load balance the plurality of signal paths.

9. The apparatus of claim 1, wherein the plurality of signal paths are retimerless signal paths.

10. The apparatus of claim 1, wherein the hybrid connector comprises:
a board mount connector; and
a cable connector stacked on the board mount connector, wherein the board mount connector connects to a first component from the first plurality of components via board traces and wherein the cable connector connects to a second component from the first plurality of components via a plurality of cables.

11. The apparatus of claim 1, further comprising:
a line card, wherein line card comprises the first plurality of components and the hybrid connector; and
a backbone card, wherein the backbone card comprises the second plurality of components.

12. The apparatus of claim 11, wherein the line card is a switch card and the backbone card is a fabric card.

13. A modular network device comprising:
a line card, the line card comprising:
a first switching processor;
a second switching processor; and
a hybrid connector, the hybrid connector connected to the first switching processor and the second switching processor;
a fabric card, the fabric card comprising:
a first fabric processor;
a second fabric processor; and
a wiring harness connecting the first fabric processor and the second fabric processor to the hybrid connector; and
a load balanced plurality of signal paths that pass through the hybrid connector, the load balanced plurality of signal paths comprising first signal paths connecting the first switching processor and the first fabric processor, second signal paths connecting the first switching processor and the second fabric processor, third signal paths connecting the second switching processor and the first fabric processor, and fourth signal paths connecting the second switching processor and the second fabric processor.

14. The modular network device of claim 13, wherein the first signal paths, the second signal paths, the third signal paths and the fourth signal paths contain the same number of signal paths.

15. The modular network device of claim 13, wherein the load balanced plurality of signal paths are retimerless signal paths.

16. The modular network device of claim 13, wherein the fabric card comprises:
a first fabric card printed circuit board (PCB) to which the first fabric processor is mounted; and
a second fabric card PCB to which the second fabric processor is mounted, wherein the first fabric card PCB and the second fabric card PCB are in a back-to-back arrangement.

17. The modular network device of claim 13, wherein the line card comprises a plurality of hybrid connectors and wherein the first switching processor and the second switching processor connect to each of the plurality of hybrid connectors.

18. The modular network device of claim 13, wherein the modular network device comprises a plurality of fabric cards and a plurality of line cards.

19. A modular network device method comprising:
providing a fabric card, the fabric card comprising:
a first fabric processor;
a second fabric processor; and
a wiring harness connecting the first fabric processor and the second fabric processor to a first connector;
connecting a line card to the fabric card, the line card comprising:
a first switching processor;
a second switching processor; and
a hybrid connector, the hybrid connector connected to the first switching processor and the second switching processor, wherein connecting the line card to the fabric card comprises connecting the first connector to the hybrid connector, wherein connecting the line card to the fabric card forms a load balanced plurality of signal paths, the load balanced plurality of signal paths comprising first signal paths connecting the first switching processor and the first fabric processor, second signal paths connecting the first switching processor and the second fabric processor, third signal paths connecting the second switching processor and the first fabric processor, and fourth signal paths connecting the second switching processor and the second fabric processor.

20. The method of claim 19, wherein the load balanced plurality of signal paths are retimerless signal paths and wherein the first signal paths, the second signal paths, the third signal paths and the fourth signal paths contain the same number of signal paths.
